(19) United States
(12) Patent Application Publication
(10) Pub. No.: US 2018/0130891 A1
(43) Pub. Date: May 10, 2018

(54) GATE STRUCTURES

(71) Applicant: GLOBALFOUNDRIES INC., Grand Cayman (KY)

(72) Inventors: Ja-Hyung HAN, Clifton Park, NY (US); Xingzhao SHI, Clifton Park, NY (US); Dinesh KOLI, Clifton Park, NY (US)

(21) Appl. No.: 15/348,356

(22) Filed: Nov. 10, 2016

(51) Int. Cl. H01L 29/423; H01L 29/40; H01L 21/3105

(52) U.S. Cl. CPC H01L 29/4238; H01L 21/31053; H01L 29/401

(57) ABSTRACT

The present disclosure generally relates to semiconductor structures and, more particularly, to gate structures with minimized gate thickness loss and methods of manufacture. The structure includes: a plurality of gate structures; a film layer provided over the gate structures and adjacent to the gate structures; and a planarized cap layer on the film and over the plurality of gate structures, the planarized cap layer having a different selectivity to slurry of a chemical mechanical polishing (CMP) process than the film.

### FIELD OF THE INVENTION

The present disclosure generally relates to semiconductor structures and, more particularly, to gate structures with minimized gate thickness loss and methods of manufacture.

### BACKGROUND

Gate structures can be formed within insulating material and capped with a capping material. The capping material can be planarized with a slurry of a chemical mechanical polishing (CMP) process. The capping material is typically an SiN material which has a relatively high selectivity to the insulating material, e.g., in order to control the CMP process and reduce any gate thickness loss during the CMP process of the capping layer.

It has been found, though, that the slurry does not show a high selectivity on patterned wafers even though it has a high selectivity on blanket wafers. That is, after a patterning process, e.g., reactive ion etching (RIE) process, to form recessed gate structures (e.g., patterned wafers), the slurry no longer shows a high selectivity to the insulating material, compared to non-patterned wafers. This results in gate thickness loss due to the difficulty in controlling the CMP process during the planarizing of the capping layer. The probable cause of this loss of selectivity is due to the insulating layer surrounding the gate structures being damaged or somehow its properties being modified or changed during the patterning process (e.g., etching process). This phenomenon is especially profound after tungsten recess etching processes.

### SUMMARY

In an aspect of the disclosure a structure comprises: a plurality of gate structures; a film layer provided over the gate structures and adjacent to the gate structures; and a planarized cap layer on the film and over the plurality of gate structures, the planarized cap layer having a different selectivity to a slurry of a chemical mechanical polishing (CMP) process than the film.

In an aspect of the disclosure a structure comprises: a plurality of recessed gate structures formed in recesses of an insulating material having modified properties due to an etching process performed on the recessed gate structures; an undamaged film directly over the plurality of recessed gate structures and insulating material; and a planarized capping material over the undamaged film.

In an aspect of the disclosure a method comprises: forming a plurality of gate structures in recesses of an insulating material; recessing the plurality of gate structures within the recesses of the insulating material; forming a film directly over the plurality of recessed gate structures and insulating material, after the recessing step; forming a capping material over the film which has a different selectivity to slurry of a chemical mechanical polishing (CMP) process than the film; and planarizing the capping material with the slurry of the CMP which stops at the film.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a gate structure, amongst other features, and respective fabrication processes in accordance with aspects of the present disclosure.

FIG. 2 shows recesses, amongst other features, and respective fabrication processes in accordance with aspects of the present disclosure.

FIG. 3 shows a cap material over a layer of film, amongst other features, and respective fabrication processes in accordance with aspects of the present disclosure.

FIG. 4 shows a planarized cap material on the gate structures, amongst other features, and respective fabrication processes in accordance with aspects of the present disclosure.

### DETAILED DESCRIPTION

The present disclosure generally relates to semiconductor structures and, more particularly, to gate structures with minimized gate thickness loss and methods of manufacture. In more specific embodiments, a layer of film is deposited over a tungsten material of the gate structure, prior to a chemical mechanical planarization (CMP) process. Advantageously, the layer of film will protect the gate structure during a polishing process, thereby minimizing gate thickness loss.

In embodiments, the layer of film can be an oxide material or amorphous carbon material, amongst other materials. For example, the layer of film can be a material that is highly selective with respect to an overlying capping material. In this way, the layer of film will act as a stopping layer during a chemical mechanical polishing (CMP) process. By acting as a stopping layer, the layer of film will minimize gate thickness loss during CMP processes. The capping material can be a SiN material.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structure of the present disclosure have been adopted from integrated circuit (IC) technology. For example, the structures are built on wafers and are realized in films of material patterned by photolithographic processes on the top of a wafer. In particular, the fabrication of the structure uses three basic building blocks: (i) deposition of thin films of material on a substrate, (ii) applying a patterned mask on top of the films by photolithographic imaging, and (iii) etching the films selectively to the mask.

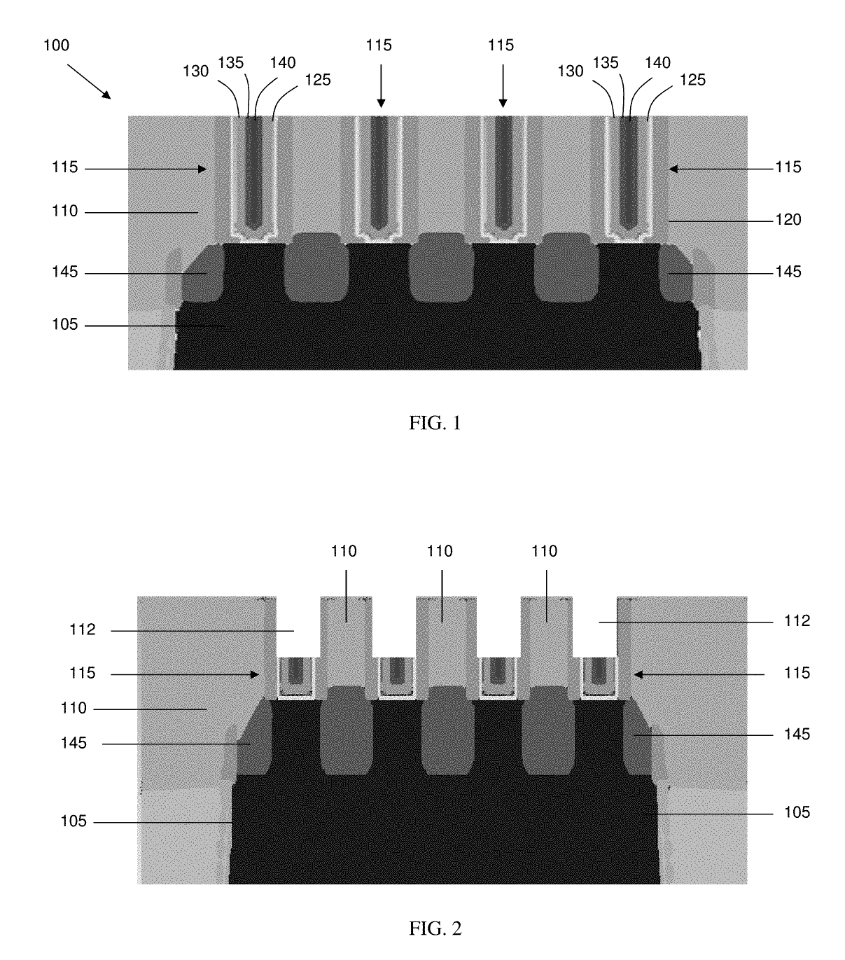

FIG. 1 shows a structure and respective fabrication processes in accordance with aspects of the present disclosure. More specifically, FIG. 1 illustrates a structure 100 comprising a substrate 105 composed of a bulk semiconductor material. For example, the substrate 105 may be composed of any suitable material including, but not limited to, Si, SiGe, SiGeC, SiC, GaAs, InAs, InP, etc. An insulating layer 110 is formed over the substrate 105 using, e.g., conventional deposition methods. For example, the insulating layer 110 can be an oxide layer formed by conventional chemical vapor deposition (CVD) processes.

In embodiments, the insulator layer 110 can be patterned to form recesses (trenches) 112, using conventional lithography and etching processes. For example, a resist can be deposited on the insulator layer 110, followed by exposure to energy (light) to form a pattern (openings). A reactive ion etching (RIE) with a selective chemistry can then be used for etching the insulator layer 110 to form the recesses 112. The resist can then be removed by an oxygen ashing or other conventional stripant.

Still referring to FIG. 1, a gate structure 115 can be formed within the recesses 112. For example, a sidewall material 120, e.g., nitride, can be deposited on the sidewalls of the recesses 112, followed by an etching process to remove any material from a bottom of the recesses 112. In embodiments, the etching process can be an isotropic etching process that is selective to the sidewall material. A dielectric material 125, e.g., high-k dielectric material, can be deposited within the recesses 112, followed by deposition of a workfunction metal 130. In embodiments, the high-k dielectric material 125 can be a hafnium based material (amongst other materials) deposited using a conventional plasma enhanced CVD (PEVCD) process. The workfunction metal 130 can be any metal or combination of metals, depending on the particular application and design parameters. A Ti or TiN layer 135 can be deposited over the workfunction metal 130, followed by a conductive gate metal 140. For example, in embodiments, the conductive gate metal 140 can be a tungsten (W) material.

The gate structures 115 also include source and drain regions (S/D) regions 145 formed in the substrate 105. The source and drain regions (S/D) regions 145 can be formed by any conventional method. For example, the source and drain regions (S/D) regions 145 can be formed by an ion implantation process, doping process or through a diffusion processes, as is well known to those of skill in the art such that no further explanation is required for an understanding of the present disclosure.

As shown in FIG. 2, the gate structures 115 undergo an etching process to recess the gate material within the recesses 112. In embodiments, the etching process is a tungsten RIE process to recess the gate structures 115 within the recesses 112. It should be understood that the tungsten RIE process can damage or change (modify) the properties of the insulator layer 110, e.g., oxide material. By damaging or changing the properties of the insulator layer 110, poor etching selectivity will result with respect to capping materials for later CMP processes. For example, during the tungsten RIE process, an etching gas, e.g., Boron, can penetrate the insulator layer 110 and change the properties (e.g., oxide properties) which, in turn, increases oxide removal rate during subsequent CMP processes of the capping layer. In this way, a change in the material properties can decrease the selectivity of the insulator layer 110 during the CMP processes resulting in gate thickness loss. As should be understood by those of skill in the art, the oxide removal rate increases as Boron concentration increases.

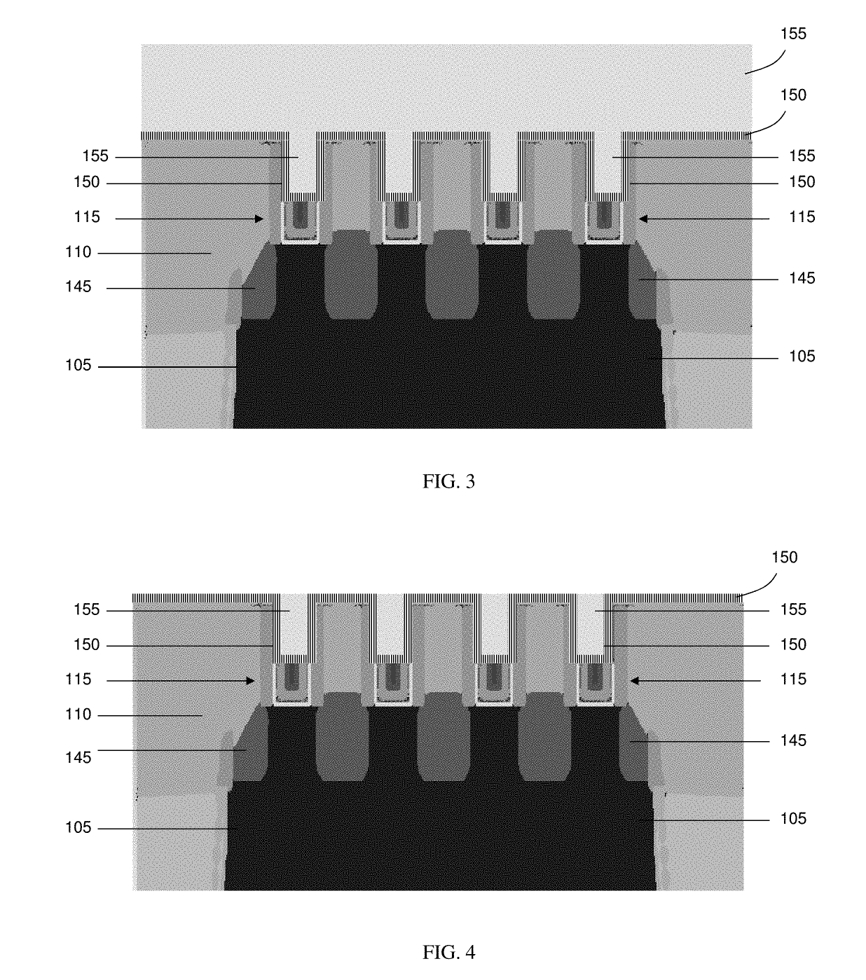

As shown in FIG. 3, to prevent gate thickness loss during subsequent CMP processes, a film 150 is formed over the gate structure 115 and the insulator layer 110. In embodiments, the film 150 can be deposited within the recesses 112 and over the gate 115 by conventional deposition processes, e.g., CVD processes. A capping layer 155 is formed over the film 150 by a conventional CVD or atomic layer deposition (ALD) process. As an example, the capping layer 155 is SiN based materials.

In embodiments, the film 150 can be deposited to a thickness of about 3 nm to about 10 nm; although other dimensions are also contemplated by the present disclosure. In embodiments, the film 150 is an oxide material or an amorphous carbon material or any material having selectivity to SiN film including SiC or Poly-Si amorphous Si, for example, which is not damaged due to an etching process. In other words, as the film 150 is deposited after the tungsten RIE process, the properties of the film 150 will not be changed, modified or damaged, resulting in a high selectivity to the etch chemistries of the subsequent CMP process, e.g., the film 150 provides a stop layer for CMP processes. In other embodiments, the film 150 can be any material that provides an etch stop layer for subsequent CMP processes of a capping layer. For example, the film 150 can be any material that is highly selective to the slurry of the CMP process for the capping material.

FIG. 4 shows a planarized capping layer 155 on the gate structures 115, amongst other features, and respective fabrication processes in accordance with aspects of the present disclosure. More specifically, in FIG. 4, the capping layer 155 undergoes a polishing process, which stops of the film 155. By using the film 150, which acts as a selective stop layer to the slurry of the CMP process of the capping layer 155, it is now possible to minimize gate loss and maintain the gate structures 115 at a desirable height. Depending on the design parameters, the film 150 can be removed from the insulator layer 110, following completion of the CMP process. Alternatively, the film 150 can remain after the CMP process is completed such that the planarized capping layer 155 is planar with a surface of the film 150.

In the example noted herein, the SiN (capping layer 155) to oxide (film 150) selectivity can be greater than (>) 50:1. In comparison, a damaged oxide material can have a selectivity of less than (<) 2:1. Accordingly, by using the film 150 as a stop layer, it is possible to prevent gate thickness loss during a CMP process of the capping material 155. For example and by comparison, the polishing rate for a patterned wafer is about 550 Å/min due to the damaged or changed (modified) properties of the oxide layer during the RIE process. On the other hand, as the film 150 is provided on the structure subsequent to the RIE process and hence does not exhibit any property changes, due to the polishing rate of about 30 Å/min. Therefore, the film 150 provides excellent selectivity to the CMP process, effectively stopping the CMP process on the film 150 and minimizing any gate thickness loss. In addition to minimizing gate loss, the film 150 allows for an increased SiN CMP process window. Another advantage includes improved CMP uniformity.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a plurality of gate structures comprising sidewall spacers;
an insulator material between the gate structures with a surface coplanar with an upper surface of the sidewall spacers;
a film layer provided over the gate structures and adjacent to the gate structures including over the coplanar surfaces of the insulator material and the sidewall spacers; and
a planarized cap layer on the film layer and over the plurality of gate structures, the planarized cap layer having a different selectivity to slurry of a chemical mechanical polishing (CMP) process than the film layer.

2. The structure of claim 1, wherein the plurality of gate structures include a tungsten fill material.

3. The structure of claim 2, wherein the film layer is an etch stop film to the slurry of the CMP process.

4. The structure of claim 1, wherein the film layer is an oxide material.

5. The structure of claim 4, wherein the planarized cap layer is composed of an SiN material.

6. The structure of claim 1, wherein the film layer is an amorphous carbon material.

7. The structure of claim 6, wherein the planarized cap layer is composed of an SiN material.

8. The structure of claim 1, wherein the film layer has a thickness in a range of about 3 nm to about 10 nm.

9. The structure of claim 1, wherein the plurality of gate structures are recessed gate structures formed in a recess of oxide material, and the film layer is an undamaged oxide material having an etch selectivity greater than 50:1 with respect to the planarized cap layer.

10. The structure of claim 9, wherein the film layer is provided over the insulating material adjacent to the plurality of gate structures and has a surface planar with the planarized cap layer.

11. A structure comprising:
a plurality of recessed gate structures formed in recesses of an insulating material having modified properties due to an etching process performed on the recessed gate structures;
an undamaged film directly over the plurality of recessed gate structures and the insulating material; and
a planarized capping material over the undamaged film, wherein the undamaged film has an etch selectivity different than the planarized capping material.

12. The structure of claim 11, wherein the plurality of recessed gate structures include tungsten material.

13. The structure of claim 12, wherein the undamaged film and the planarized capping material have different selectivity to a CMP slurry used in polishing of the capping material.

14. The structure of claim 13, wherein the undamaged film is amorphous carbon material and the planarized capping material is SiN material.

15. The structure of claim 14, wherein the insulating material is oxide.

16. The structure of claim 13, wherein the undamaged film is oxide and the planarized capping material is SiN material.

17. The structure of claim 11, wherein the undamaged film has a thickness in a range of about 3 nm to about 10 nm.

18. The structure of claim 11, wherein the undamaged film is in recesses of the insulating material, directly on the gate structures, and directly on the insulating material outside of the recesses.

19. The structure of claim 11, wherein the planarized capping material is planarized to a surface of the undamaged film.

20. (canceled)

21. The structure of claim 10, wherein the recessed gate structures comprise recessed dielectric materials and workfunction metals while the sidewall spacers remain at an original height.
